(19) United States
(12) Patent Application Publication
(10) Pub. No.: US 2024/0234270 A1
(43) Pub. Date: Jul. 11, 2024

(54) SEMICONDUCTOR DEVICE AND METHOD FOR MAKING THE SAME

(71) Applicant: STATS ChipPAC Pte. Ltd., Singapore (SG)

(72) Inventors: ChangOh KIM, Incheon (KR); JinHee JUNG, Incheon (KR); OMin KWON, Incheon (KR)

(21) Appl. No.: 18/395,626

(22) Filed: Dec. 25, 2023

(30) Foreign Application Priority Data
Jan. 5, 2023 (CN) 202310014562.0

(51) Int. Cl. H01L 23/498; H01L 21/48; H01L 21/56; H01L 23/538; H01L 23/552; H01L 25/16

(52) U.S. Cl. CPC H01L 23/49811; H01L 21/4853; H01L 21/565; H01L 23/5383; H01L 23/552; H01L 25/165; H01L 24/16; H01L 2224/16225

(57) ABSTRACT

A semiconductor device and a method for making the same are provided. The method includes: providing a substrate having a first surface and a second surface opposite to the first surface, wherein a plurality of conductive pillars are formed on the second surface of the substrate; forming a polyimide layer on the second surface of the substrate to cover the plurality of conductive pillars; mounting a first electronic component on the first surface of the substrate; and forming a first encapsulant on the first surface of the substrate to cover the first electronic component.

### TECHNICAL FIELD

The present application relates generally to semiconductor technology, and more particularly, to a semiconductor device and a method for making such semiconductor device.

### BACKGROUND OF THE INVENTION

The semiconductor industry is constantly faced with complex integration challenges as consumers want their electronics to be smaller, faster and higher performance with more and more functionalities packed into a single device. One of the solutions is System-in-Package (SiP). SiP is a functional electronic system or sub-system that includes in a single package two or more heterogeneous semiconductor dice, such as a logic chip, a memory, integrated passive devices (IPD), RF filters, sensors, heat sinks, or antennas. Recently, SiP uses Double Side Molding (DSM) technology to further shrink the overall package size. Oftentimes, fine-pitch copper (Cu) posts are used in the DSM technology. However, the Cu posts are susceptible to damages during a surface mounting process, resulting in low reliability of SiPs incorporating such Cu posts.

Therefore, a need exists for a more reliable double side molding process.

### SUMMARY OF THE INVENTION

An objective of the present application is to provide a method for making a semiconductor device with higher reliability.

According to an aspect of the present application, a method for making a semiconductor device is provided. The method may include: providing a substrate having a first surface and a second surface opposite to the first surface, wherein a plurality of conductive pillars are formed on the second surface of the substrate; forming a polyimide layer on the second surface of the substrate to cover the plurality of conductive pillars; mounting a first electronic component on the first surface of the substrate; and forming a first encapsulant on the first surface of the substrate to cover the first electronic component.

According to another aspect of the present application, a semiconductor device is provided. The semiconductor device may include: a substrate having a first surface and a second surface opposite to the first surface; a plurality of conductive pillars disposed on the second surface of the substrate; a polyimide layer disposed on the second surface of the substrate and surrounding the plurality of conductive pillars; a first electronic component mounted on the first surface of the substrate; and a first encapsulant disposed on the first surface of the substrate and covering the first electronic component.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 is a cross-sectional view illustrating a substrate used in a Double Side Molding (DSM) technology.

FIGS. 2A to 2C are cross-sectional views illustrating various steps of a method for forming a polyimide layer on a substrate according to an embodiment of the present application.

FIGS. 3A to 3B are cross-sectional views illustrating various steps of a method for forming a polyimide layer on a substrate according to another embodiment of the present application.

FIGS. 4A to 4K are cross-sectional views illustrating various steps of a method for making a semiconductor device according to an embodiment of the present application.

FIGS. 5A to 5H are cross-sectional views illustrating various steps of a method for making a semiconductor device according to another embodiment of the present application.

FIG. 6 is a cross-sectional view of a semiconductor device according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

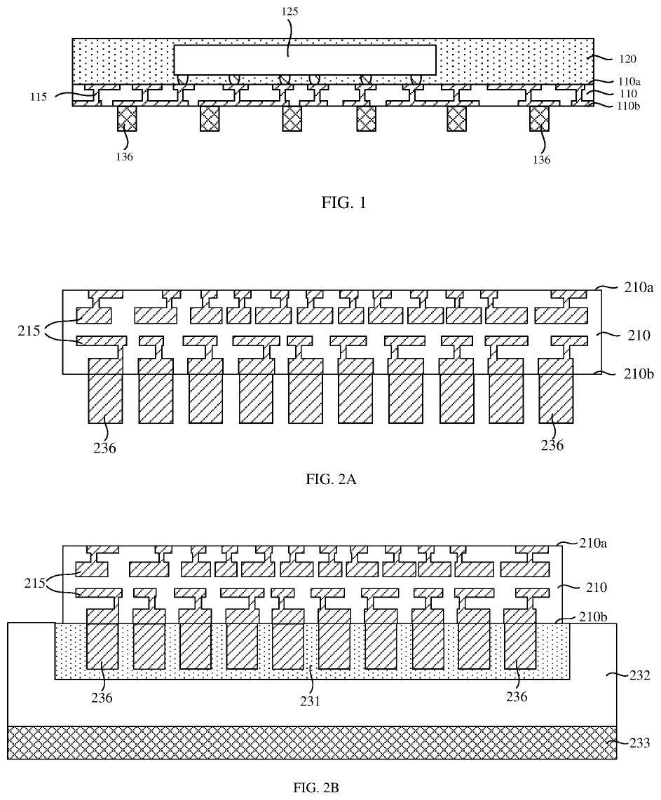

FIG. 1 illustrates a cross-sectional view of a substrate 110 used in a Double Side Molding (DSM) process. As shown in FIG. 1, the substrate 110 has a first surface 110a and a second surface 110b opposite to the first surface 110a. A redistribution structure (RDS) 115 is formed in the substrate 110. The RDS 115 includes one or more dielectric layers and one or more conductive layers between and through the dielectric layers. A plurality of conductive pillars (for example, copper posts) 136 are formed on the second surface 110b of the substrate 110 and electrically connected to respective conductive patterns of the RDS 115. The conductive pillars 136 can be used to mount one or more electronic components on the second surface 110b of the substrate 110, and enable therethrough the connection of the RDS 115 in the substrate 110 with an exterior device or system. An electronic component 125 is mounted on the first surface 110a of the substrate 110. A top encapsulant 120 is formed on the first surface 110a and covers the electronic component 125 to protect against thermal shock, physical attach, fluid penetration, etc. However, the conductive pillars 136 on the second surface 110b are susceptible to damages when the electronic component 125 and the top encapsulant 120 are formed on the substrate 110.

In a co-pending Chinese patent application Ser. No. 20/221,0305657.3, it is described that ultraviolet (UV) tapes may be used to protect conductive pillars on a substrate, such as the conductive pillars 136 in the above FIG. 1. In particular, a UV tape (not shown) may be laminated on the second surface 110b of the substrate 110 to cover the conductive pillars 136. Since the height of the conductive pillars 136 is generally much greater than a thickness of a single layer of UV tape, many layers of UV tapes are required to be stacked together to cover the conductive pillars 136, resulting in excess cost and poor total thickness variation (TTV). Moreover, the UV-tape lamination may delaminate due to shrinkage during a reflow process of solder paste formed on the substrate 110, and residues may be left on the substrate 110 when the UV-tape lamination is removed, resulting in low reliability.

To address at least one of the above problems, a method for making a semiconductor device is provided in an aspect of the present application. In the method, a polyimide layer is formed on a surface of a substrate to cover conductive pillars formed on the surface. The polyimide layer has high thermal resistance and high insulating performance, and thus can protect the conductive pillars from high pressure and high temperature during a molding process. Further, after the molding process, the polyimide layer can be easily removed by a chemical etching process to avoid residues left on the substrate.

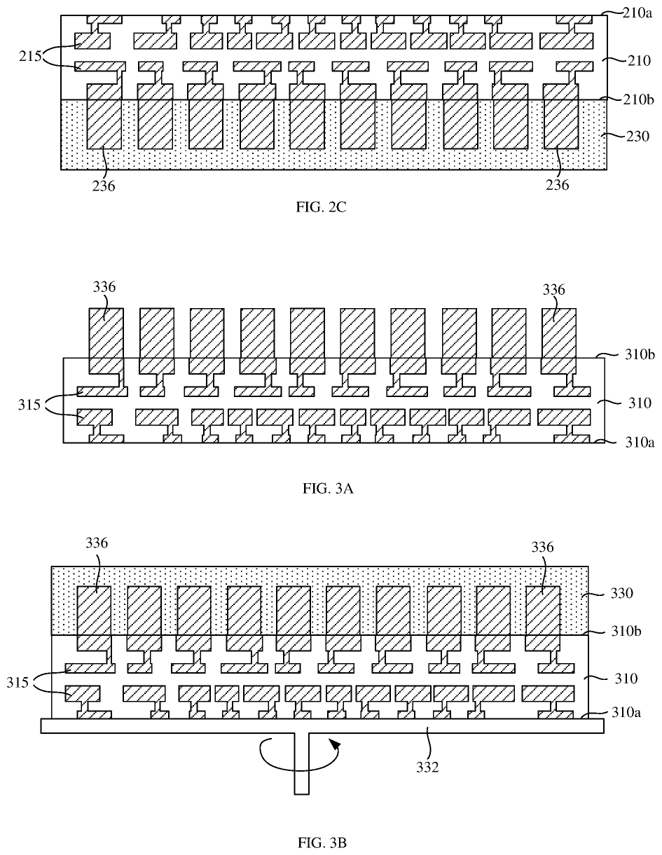

Referring to FIGS. 2A to 2C, cross-sectional views illustrating various steps of a method for forming a polyimide layer on a substrate are illustrated according to an embodiment of the present application.

As shown in FIG. 2A, a substrate 210 is provided. The substrate 210 has a first surface 210a and a second surface 210b opposite to the first surface 210a. In some embodiments, the substrate 210 may be a laminate interposer, PCB, wafer-form, strip interposer, leadframe, or any other suitable substrate. The substrate 210 may include one or more insulating or passivation layers, one or more conductive vias formed through the insulating layers, and one or more conductive layers formed over or between the insulating layers. The substrate 210 may include one or more laminated layers of polytetrafluoroethylene pre-impregnated, FR-4, FR-1, CEM-1, or CEM-3 with a combination of phenolic cotton paper, epoxy, resin, woven glass, matte glass, polyester, and other reinforcement fibers or fabrics. The insulating layers may contain one or more layers of silicon dioxide (SiO2), silicon nitride (Si3N4), silicon oxynitride (SiON), tantalum pentoxide (Ta2O5), aluminum oxide (Al2O3), or other material having similar insulating and structural properties. The substrate 210 can also be a multi-layer flexible laminate, ceramic, copper clad laminate, glass, or semiconductor wafer including an active surface containing one or more transistors, diodes, and other circuit elements to implement analog circuits or digital circuits.

In the example shown in FIGS. 2A to 2C, the substrate 210 may include redistribution structures (RDSs) 215 having one or more dielectric layers and one or more conductive layers between and through dielectric layers. The conductive layers may define pads, traces and plugs through which electrical signals or voltages can be distributed horizontally and vertically across the RDS. The RDS 215 may include one or more of Al, Cu, Sn, Ni, Au, Ag, or any other suitable electrically conductive material. It could be appreciated that, the RDS 215 may be implemented in various structures and types, but aspects of the present application are not limited to the above example.

Still referring to FIG. 2A, a plurality of conductive pillars 236 are formed on the second surface 210b of the substrate 210. The conductive pillars 236 may include one or more of Cu, Al, Sn, Ni, Au, Ag, or other suitable electrically conductive material. In an example, each conductive pillar 236 is a copper pillar, but aspects of the present disclosure are not limited thereto. The conductive pillars 236 may be formed on the second surface 210b of the substrate 210, and may be used for electrically connecting the redistribution structures in the substrate 210 with external devices. In an example, the conductive pillars 236 are formed by depositing (e.g., sputtering or plating) one or more layers of conductive material into openings of a mask layer. In other embodiments, conductive pillars 236 may be formed using another suitable metal deposition technique or surface mounting technique.

It could be understood that the substrate 210 and the pillars 236 shown in FIG. 2A are only for illustrative purpose and not limiting. In some other embodiments, one or more electronic components (for example, active devices such as semiconductor dice, semiconductor packages, discrete transistors, discrete diodes, etc., or passive devices such as capacitors, inductors, or resistors, etc.) may be attached to the second surface 210b of the substrate 210. The one or more electronic components may have a smaller height than the pillars 236. The one or more electronic components may be attached to the second surface 210b of the substrate 210 before or after the conductive pillars 236 are formed, or may be attached to the second surface 210b of the substrate 210 together with the conductive pillars 236, which is not limited in the present application.

Referring to FIG. 2B, a polyimide varnish 231 is provided and formed on the substrate 210. Specifically, the polyimide varnish 231 may be a solution having a polyimide and/or a polyimide precursor dissolved in an organic solvent, and can be used to form a smooth polyimide layer through heat treatment.

The polyimide and/or the polyimide precursor to be used for the polyimide varnish 231 of the present invention may vary according to actual needs. Usually, it is common to react and polymerize a tetracarboxylic acid derivative with a primary diamine to obtain a polyimide precursor which is subjected to ring closure imide-conversion to obtain a polyimide. In some examples, the tetracarboxylic acid derivative may include aromatic tetracarboxylic acids, alicyclic tetracarboxylic acids, aliphatic tetracarboxylic acids, etc., and the primary diamine may include aromatic diamines, aliphatic diamines, etc. In some examples, the organic solvent for dissolving the polyimide and/or the polyimide precursor may include N-methylpyrrolidone, N,N-dimethylacetamide, N,N-dimethylformamide, etc.

In the example shown in FIG. 2B, a jig 232 is provided to hold the polyimide varnish 231. Specifically, the jig 232 may be shaped as a frame having a substantially rectangular cross section, and may have an internal space having a predetermined depth in a vertical direction, and the polyimide varnish 231 can then be held in the internal space of the jig 232. Then, the substrate 210 is loaded and placed above the jig 232, and the plurality of conductive pillars 236 may be brought into the internal space of the jig 232 and immersed into the polyimide varnish 231. As shown in FIG. 2B, the second surface 210b of the substrate 210 may be in contact with the polyimide varnish 231 to transfer the polyimide varnish 231 onto the second surface 210b.

After the plurality of conductive pillars 236 are immersed into the polyimide varnish 231, the polyimide varnish 231 can be subjected to heat treatment for imide-conversion to form a polyimide layer on the substrate 210. For example, as shown in FIG. 2B, a heater 233 may be placed under the jig 232 to heat the polyimide varnish 231. The temperature for heating the polyimide varnish 231 for imide-conversion may range from 100° C. to 400° C., preferably, from 150° C. to 300° C. It can be appreciated that the heating temperature may vary depending on the specific composition of the polyimide varnish 231.

Referring to FIG. 2C, after the imide-conversion, the jig 232 and the heater 233 are removed from the substrate 210, and a polyimide layer 230 is left and formed on the second surface 210b of the substrate 210 to cover the plurality of conductive pillars 236. By virtue of the characteristics of the polyimide layer 230, such as higher mechanical strength, higher heat resistance and higher solvent resistance, the polyimide layer 230 can well protect the plurality of conductive pillars 236 from the external environment.

Referring to FIGS. 3A and 3B, cross-sectional views illustrating various steps of a method for forming a polyimide layer on a substrate are illustrated according to another embodiment of the present application.

As shown in FIG. 3A, a substrate 310 is provided. The substrate 310 has a first surface 310a and a second surface 310b opposite to the first surface 310a. One or more redistribution structures 315 may be formed in the substrate 310, and a plurality of conductive pillars 336 are formed on the second surface 310b of the substrate 310. The substrate 310, the redistribution structures 315 and the plurality of conductive pillars 336 are similar as the substrate 210, the redistribution structures 215 and the plurality of conductive pillars 236 shown in FIG. 2A, respectively, and will not be described in detail herein.

Referring to FIG. 3B, a polyimide layer 330 is formed on the second surface 310b of the substrate 310 to cover the plurality of conductive pillars 336.

In the example shown in FIG. 3B, a spinner (or spin coater) 332 is provided, and the substrate 310 is disposed on the spinner 332 with the first surface 310a attached onto a rotating stage of the spinner 332. Then, a polyimide varnish is dropped onto the second surface 310b of the substrate 310, e.g., at or close to a center of the rotating stage, and the rotating stage of the spinner 332 starts rotating. As the rotation accelerates, a centrifugal force is applied to the polyimide varnish, spreading the polyimide varnish over the entirety of the second surface 310b of the substrate 310. The thickness of the polyimide varnish can be effectively controlled by a rotation speed of the spinner. After uniformly spread on the second surface 310b of the substrate 310, the polyimide varnish is subjected to heat treatment for imide-conversion to form the polyimide layer 330 as shown in FIG. 3B. More details about the polyimide varnish and the heat treatment may refer to the above embodiments described with reference to the FIG. 2B, and will not be elaborated herein.

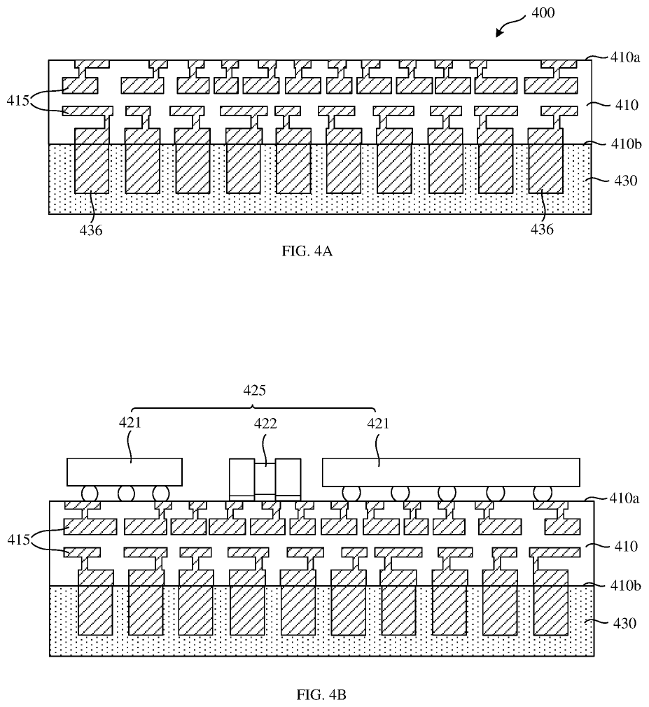

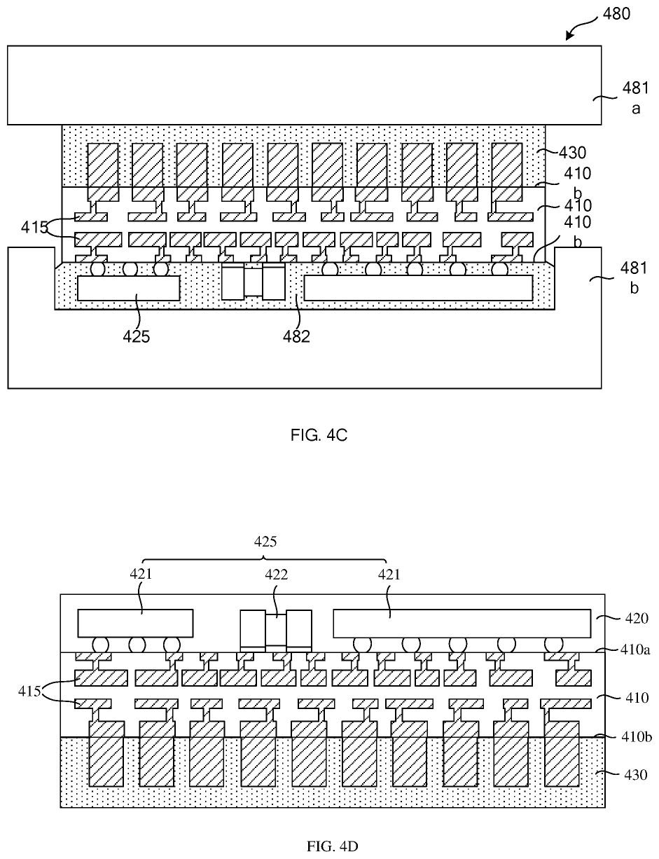

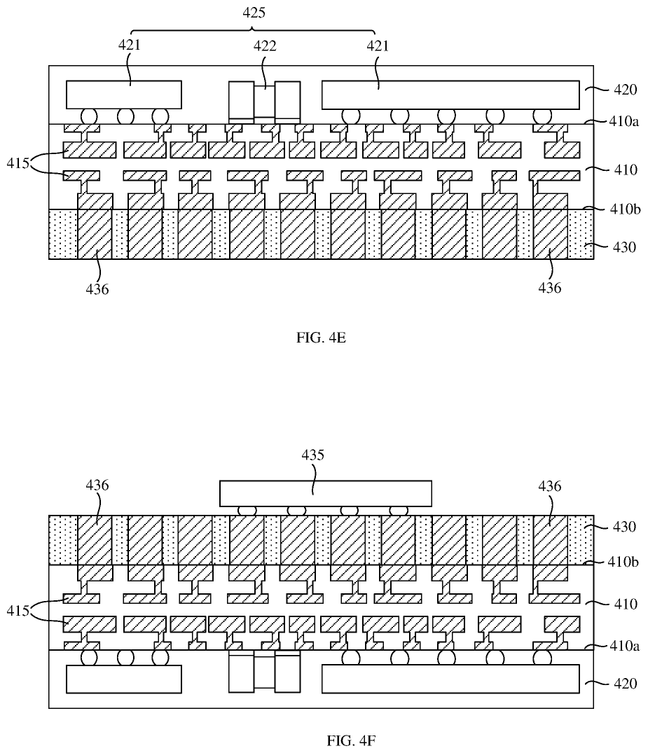

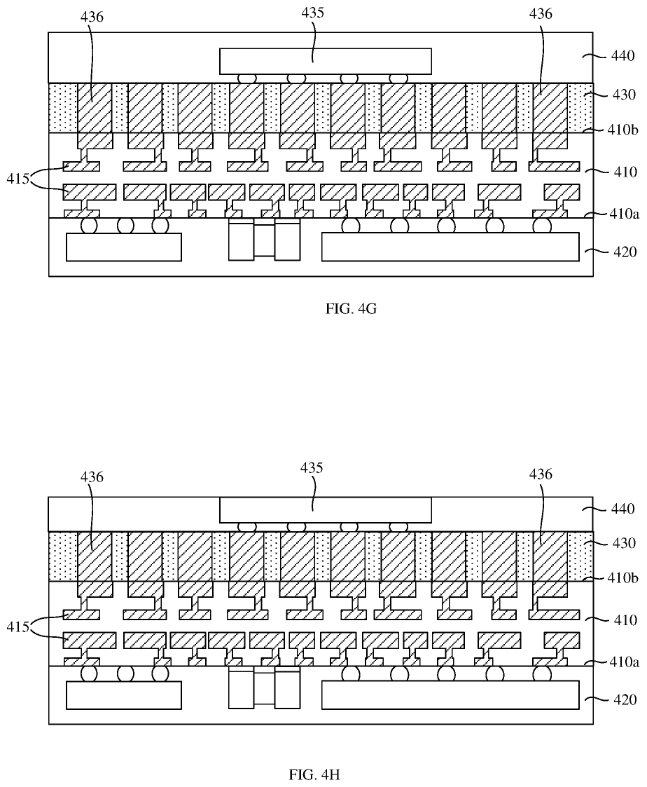

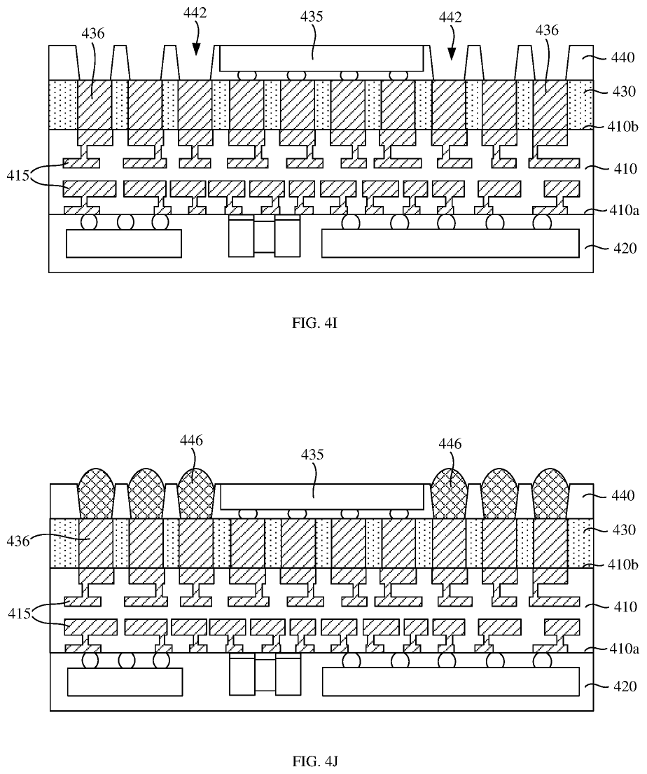

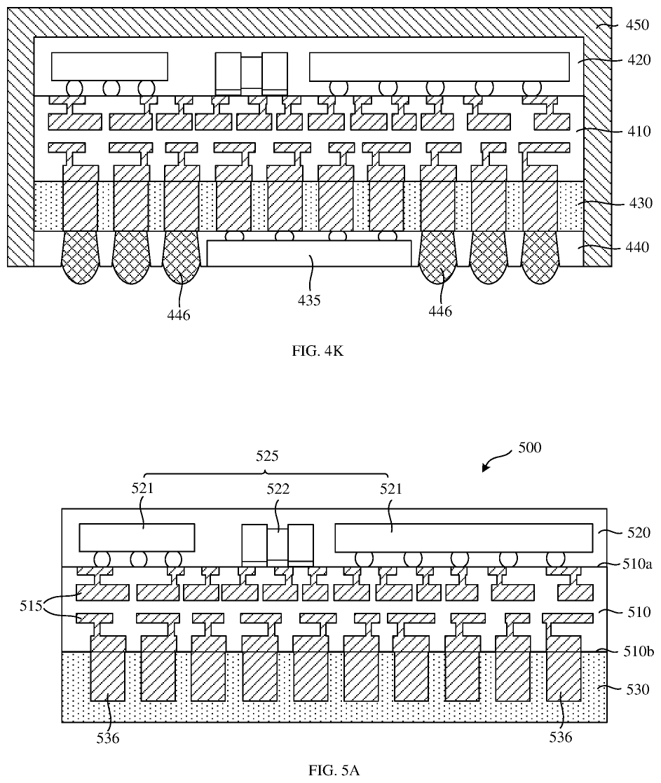

Referring to FIGS. 4A-4K, cross-sectional views illustrating various steps of a method for making a semiconductor device are illustrated according to an embodiment of the present application.

Referring to FIG. 4A, a package 400 is provided. The package 400 includes a substrate 410 having a first surface 410a and a second surface 410b opposite to the first surface 410a.

One or more redistribution structures 415 may be formed in the substrate 410, and a plurality of conductive pillars 436 are formed on the second surface 410b of the substrate 410. A polyimide layer 430 is formed on the second surface 410b of the substrate 410 and covers the plurality of conductive pillars 436. The package 400 can be formed by the method described with reference to the FIGS. 2A-2C or the method described with reference to the FIGS. 3A-3B, and will not be elaborated herein.

In some embodiments, after the polyimide layer 430 is formed on the second surface 410b of the substrate 410, a planarization process may be performed on the polyimide layer 430 to obtain a flat surface, which may facilitate the subsequent processes. For example, a grinding operation with a grinder, or another suitable chemical or mechanical grinding or etching process, can be used to planarize the polyimide layer 430.

Referring to FIG. 4B, one or more first electronic components 425 may be mounted on the first surface 410a of the substrate 410.

In some embodiments, solder paste may be deposited or printed onto top conductive patterns of the redistribution structures 415 at locations where the first electronic component(s) 425 may be surface mounted. The solder paste can be dispensed by jet printing, laser printing, pneumatically, by pin transfer, using a photoresist mask, by stencil-printing, or by another suitable process. Then, the first electronic components 425 may be mounted on the first surface 410a with terminals of the first electronic components 425 in contact with and over the solder paste. The solder paste may be reflowed to mechanically and electrically couple the first electronic components 425 to the top conductive patterns. The first electronic components 425 may include one or more semiconductor dice 421 and/or discrete devices 422. The first electronic components 425 may be passive or active devices as desired to implement any given electrical functionality within the semiconductor package to be formed. The first electronic components 425 may be active devices such as semiconductor dice, semiconductor packages, discrete transistors, discrete diodes, etc. The first electronic components 425 may also be passive devices such as capacitors, inductors, or resistors.

Referring to FIG. 4C, a molding apparatus 480 is provided. The molding apparatus 480 may be used for forming a molding material over a package. The molding apparatus 480 may include a top chase 481a and a bottom chase 481b. The top chase 481a may be used to hold the package to be molded, and the bottom chase 481b may be used to hold the molding material 482. The molding material 482 may be a solid encapsulant, such as epoxy molding compound (EMC), polyimide, epoxy, and/or the like. The top chase 481a and the bottom chase 481b may define the geometry of the molding material 482 around the package. Pressure and heat can be applied to the molding material 482, and the top chase 481a and the bottom chase 481b may compress the heated molding material 482 to a desired shape and/or geometry around the package. In some cases, the molding apparatus 480 may further include (not shown in FIG. 4C) a moving control unit to move the top chase 481a downward, the bottom chase 481b upward, or both. It could be understood that the molding apparatus 480 shown in FIG. 4C is only for illustrative purpose and not limiting.

Still referring to FIG. 4C, the substrate 410 is loaded into the molding apparatus 480, and the polyimide layer 430 is attached to the top chase 481a of the molding apparatus 480. Then, the top chase 481a and the bottom chase 481b may be moved to each other to compress the molding material 482, and a pressure and heating process may be applied to the molding material 482. The heat and pressure within the molding apparatus 480 may be sufficient to cure the molding material 482. The top chase 481a and the bottom chase 481b may compress the heated molding material (for example, liquid and/or un-cured molding material) to the required shape and/or geometry around the first electronic component 425 mounted on the first surface 410b of the substrate 410 until the molding material 482 is cured. After the molding material 482 is cured, the top chase 481a and the bottom chase 481b are separated from each other, and the substrate 410 is removed from the molding apparatus 480.

As shown in FIG. 4D, a first encapsulant 420 is formed on the first surface 410a of the substrate 410 after the substrate 410 is removed from the molding apparatus 480. The first encapsulant 420 may protect the first electronic component 425 from external elements and contaminants. It could be understood that the compression molding process shown in FIGS. 4C and 4D are only for illustrative purpose and not limiting. In other embodiments, the first encapsulant 420 can also be formed using a paste printing, transfer molding, liquid encapsulant molding, vacuum lamination, spin coating, or other suitable applicator.

Because of its high thermal resistance and high insulating performance, the polyimide layer 430 can not only protect the plurality of conductive pillars 436 from the external environment during the molding process, but also serve as an insulating layer in the semiconductor device to be formed. That is, there may be no need to remove the polyimide layer 430 after the molding process, which can reduce the complexity of the manufacturing process.

Referring to FIG. 4E, a portion of a thickness of the polyimide layer 430 is removed to expose the plurality of conductive pillars 436. In some embodiments, a backgrinding operation with a grinder, or another suitable chemical or mechanical grinding or etching process, can be used to reduce the thickness of the polyimide layer 430 and expose the conductive pillars 436. By removing a portion of the polyimide layer 430, a surface of the polyimide layer 430 may be coplanar with a surface of the conductive pillars 436, and both the surface of the polyimide layer 430 and the surface of the conductive pillars 436 can be cleaned.

Afterwards, as shown in FIG. 4F, a second electronic component 435 is mounted on a first set of the plurality of conductive pillars 436. For example, the substrate 410 is flipped with the second surface 410b oriented upward. Solder paste may be patterned onto the first set of conductive pillars 436 (e.g., the four conductive pillars 436 in the middle shown in FIG. 4F), and then the second electronic component 435 is surface mounted on the first set of conductive pillars 436 through the solder paste. In the example shown in FIG. 4F, the second electronic component 435 is shown as a semiconductor die. In some other embodiments, a plurality of semiconductor dice or one or more discrete devices can be surface mounted on respective portions of the conductive pillars 436.

Referring to FIG. 4G, a second encapsulant 440 is formed on the polyimide layer 430. The second encapsulant 440 may cover the exposed surfaces of the plurality of conductive pillars 436 and the second electronic component 435.

The second encapsulant 440 is non-conductive and can protect the second electronic component 435 and the conductive pillars 436 from external elements and contaminants. In some cases, the second encapsulant 440 may be formed using a process similar to the compression molding process for forming the first encapsulant 420. In some cases, the second encapsulant 440 may be formed using a paste printing, transfer molding, liquid encapsulant molding, vacuum lamination, spin coating, or other suitable applicator. The second encapsulant 440 and the first encapsulant 420 may be made of the same material, for example, an epoxy-based resin.

Referring to FIG. 4H, the second encapsulant 440 is planarized to expose the second electronic component 435. In some embodiments, a backgrinding operation with a grinder, or another suitable chemical or mechanical grinding or etching process, can be used to reduce a thickness of the second encapsulant 440 and expose a top surface of the second electronic component 435. By removing portions of the second encapsulant 440, a top surface of the second encapsulant 440 may be coplanar with the top surface of the second electronic component 435.

Referring to FIG. 4I, one or more cavities 442 may be formed in the second encapsulant 440 to expose top surfaces of a second set of conductive pillars 436 (e.g., the six conductive pillars 436 besides the second electronic component 435 as shown in FIG. 4I). Each cavity 442 may expose at least a top surface of a respective conductive pillar 436. In some embodiments, a laser ablation process may be employed to form the cavities 442 in the second encapsulant 440. In some embodiments, the cavities 442 may be formed by an etching process, or any other process known in the art so long as the encapsulant material above the conductive pillars 436 can be removed. In some embodiments, after forming the cavities 442, a cleaning process may further be performed to remove residuals.

Referring to FIG. 4J, a bump 446 may be formed in each of the cavities and in electrical contact with a respective conductive pillar 436.

In some embodiments, an electrically conductive bump material may be deposited into the cavities of the second encapsulant 440 using one of or any combination of the following processes: evaporation, electrolytic plating, electroless plating, ball drop, or screen printing process. The conductive bump material may include Al, Sn, Ni, Au, Ag, Pb, Bi, Cu, solder, and combinations thereof, with an optional flux solution. For example, the conductive bump material may be solder paste, and the solder paste is printed into the cavities. Then, the conductive bump material may be reflowed by heating the material above its melting point to form conductive balls or bumps 446. Each bump 446 may cover the exposed surface of a respective conductive pillar 436. The bumps 446 may extend over the top surface of the second encapsulant 440, and enable electrical connection between the internal circuitry of the semiconductor device with an exterior device or system. In a case that the conductive bump material includes flux solution, a deflux operation may be further performed to clean the flux solution. In some other embodiments, the bumps 446 can also be compression bonded or thermocompression bonded to the respective conductive pillars 436. The hemispherical bump 446 shown in FIG. 4J may represent one type of interconnect structure that can be formed over the conductive pillar 436. In other examples, each of the bumps 446 may be a stud bump, a micro bump, or other electrical interconnects.

At last, referring to FIG. 4K, an electromagnetic interference (EMI) shielding layer 450 is formed, and the EMI shielding layer 450 may at least cover the top and lateral surfaces of the first encapsulant 420.

The EMI shielding layer 450 may be formed from copper, aluminum, iron, or any other suitable material for EMI shielding. In some embodiments, the EMI shielding layer 450 may be formed by spray coating, plating, sputtering, or any other suitable metal deposition process. The EMI shielding layer 450 may be a conformal shield that follows the shapes and/or contours of the first encapsulant 420, the substrate 410, the polyimide layer 430 and the second encapsulant 440. Specifically, as shown in FIG. 4K, the EMI shielding layer 450 covers the top and lateral surfaces of the first encapsulant 420, the lateral surface of the substrate 410, the lateral surface of the polyimide layer 430, and the lateral surface of the second encapsulant 440. However, the bumps 446, the bottom surface of the second encapsulant 440 and the bottom surface of the second electronic component 435 are exposed from the EMI shielding layer 450. The EMI shielding layer 450 can shield EMI or other interferences induced to (or generated by) the electronic components within semiconductor device.

In some embodiments, in order to form multiple semiconductor devices simultaneously, the steps described above can be performed on a strip-based substrate. The strip-base substrate can be singulated into individual semiconductor devices after the bumps are formed on the conductive pillar, and then the EMI shielding layer can be formed on each individual semiconductor device.

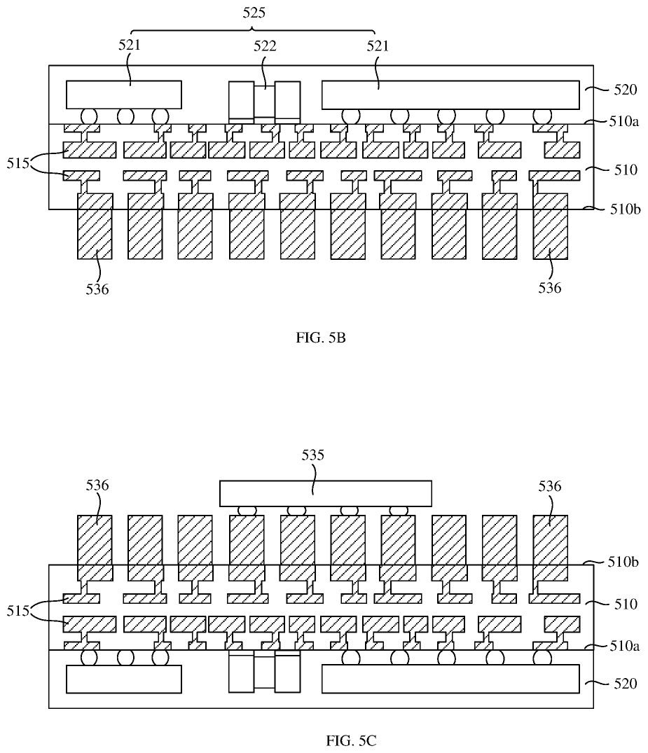

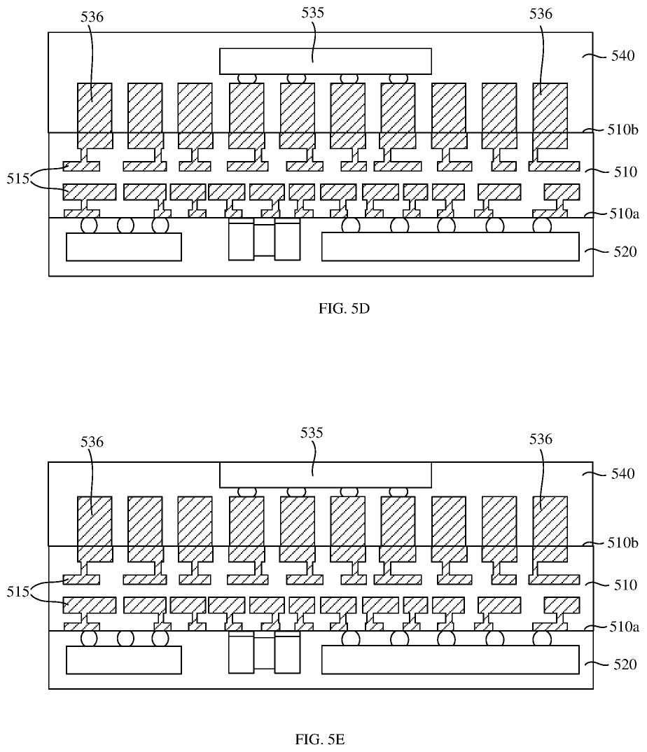

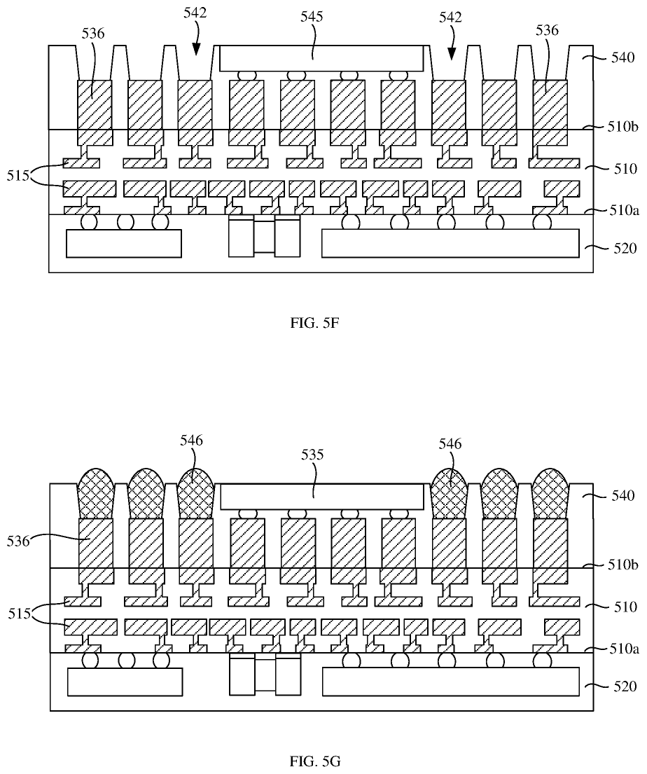

Referring to FIGS. 5A-5H, cross-sectional views illustrating various steps of a method for making a semiconductor device are illustrated according to another embodiment of the present application. Different from the embodiments described with reference to FIGS. 4A-4K, the polyimide layer is not left in the semiconductor device to be formed, but is removed.

Referring to FIG. 5A, a package 500 is provided. The package 500 includes a substrate 510 having a first surface 510a and a second surface 510b opposite to the first surface 510a. One or more redistribution structures 515 may be formed in the substrate 510, and a plurality of conductive pillars 536 are formed on the second surface 510b of the substrate 510. A polyimide layer 530 is formed on the second surface 510b of the substrate 510 and covers the plurality of conductive pillars 536. A first electronic component 525 is mounted on the first surface 510a of the substrate 510, and a first encapsulant 520 is also formed on the first surface 510a of the substrate 510 and covers the first electronic component 525. The package 500 can be formed by the method described with reference to the FIGS. 4A-4D, and will not be elaborated herein.

Referring to FIG. 5B, the polyimide layer 530 is removed from the second surface 510b of the substrate 510. Specifically, a chemical etching process may be employed to remove the polyimide layer 530. For example, an alkaline solution such as potassium hydroxide (KOH) and sodium hydroxide (NaOH), or an ethylenediamine solution may be used to etch the polyimide layer 530. As the polyimide layer 530 can be easily removed by the chemical etching process, there may be no or less damages to other components in the semiconductor device to be formed. However, the present application is not limited thereto. In other embodiments, a dry etching process such as a reactive ion etch (RIE) or inductively coupled plasma (ICP) etching process may be employed to remove the polyimide layer 530.

Afterwards, as shown in FIG. 5C, a second electronic component 535 is mounted on a first set of the plurality of conductive pillars 536. For example, the substrate 510 is flipped with the second surface 510b oriented upward, and the second electronic component 535 can be surface mounted on the four conductive pillars 536 in the middle through solder paste.

Referring to FIG. 5D, a second encapsulant 540 is formed on the second surface 510bof the substrate 510. The second encapsulant 540 may fill gaps between the plurality of the conductive pillars 536 and cover the second electronic component 535. The second encapsulant 540 may be formed using a compression molding, transfer molding, liquid encapsulant molding, vacuum lamination, spin coating, paste printing, or another suitable applicator. The second encapsulant 540 and the first encapsulant 520 may be made of the same material, for example, an epoxy-based resin.

Referring to FIG. 5E, the second encapsulant 540 is planarized to expose the second electronic component 535. By removing a portion of the second encapsulant 540, a top surface of the second encapsulant 540 may be coplanar with the top surface of the second electronic component 535.

Referring to FIG. 5F, one or more cavities 542 may be formed in the second encapsulant 540 to expose top surfaces of a second set of conductive pillars 536 (e.g., the six conductive pillars 536 besides the second electronic component 535). Each cavity 542 may expose at least a top surface of a respective conductive pillar 536.

Referring to FIG. 5G, a bump 546 may be formed in each of the cavities to electrically connect with a respective conductive pillar 536. The bump 546 may extend over the top surface of the second encapsulant 540.

Afterwards, referring to FIG. 5H, an electromagnetic interference (EMI) shielding layer 550 is formed, and the EMI shielding layer 550 may at least cover the top and lateral surfaces of the first encapsulant 520. The EMI shielding layer 550 may be a conformal shield that follows the shapes and/or contours of the first encapsulant 520, the substrate 510 and the second encapsulant 540. Specifically, as shown in FIG. 5H, the EMI shielding layer 550 covers the top and lateral surfaces of the first encapsulant 520, the lateral surface of the substrate 510, and the lateral surface of the second encapsulant 540. The EMI shielding layer 550 can shield EMI or other interferences induced to (or generated by) the electronic components within semiconductor device.

While the process for making the semiconductor device is illustrated in conjunction with FIGS. 2A-2C, FIGS. 3A-3B, FIGS. 4A-4K, and FIGS. 5A-5H, it will be appreciated by those skilled in the art that modifications and adaptations to the process may be made without departing from the scope of the present invention.

According to another aspect of the present application, a semiconductor device is provided.

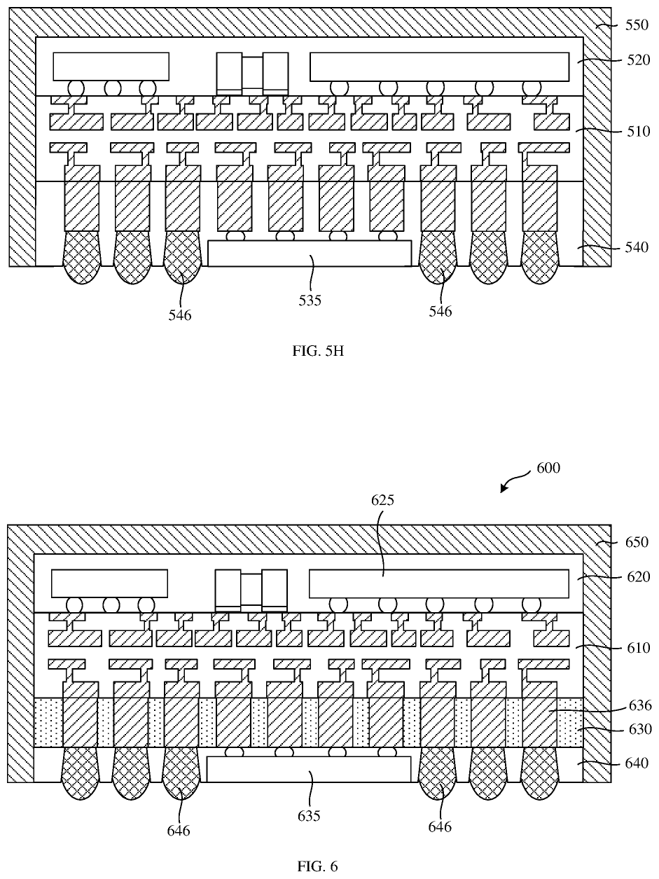

Referring FIG. 6, a cross-sectional view of a semiconductor device 600 is illustrated according to an embodiment of the present application. The semiconductor device 600 may include a substrate 610 having a first surface and a second surface opposite to the first surface.

A plurality of conductive pillars 636 is disposed on the second surface of the substrate 610. A polyimide layer 630 is disposed on the second surface of the substrate 610 and surrounds the plurality of conductive pillars 636. A first electronic component 625 is mounted on the first surface of the substrate 610; and a first encapsulant 620 is disposed on the first surface of the substrate 610 and covers the first electronic component 625.

In some embodiments, as shown in FIG. 6, a top surface of each of the plurality of conductive pillars 636 is substantially flush with a top surface of the polyimide layer 636. In some embodiments, the semiconductor device 600 may further include: a second electronic component 635 mounted on a first set of the plurality of conductive pillars 636; a plurality of bumps 646 disposed on and electrically connected with a second set of the plurality of conductive pillars 636, respectively; and a second encapsulant 640 disposed on the polyimide layer 630 and surrounding the plurality of bumps 646 and the second electronic component 635. In some embodiments, the semiconductor device 600 may further include an electromagnetic interference (EMI) shielding layer 650 at least covering the first encapsulant 620.

The semiconductor device 600 can be formed by the methods described with reference to FIGS. 2A-2C, FIGS. 3A-3B and FIGS. 4A-4K, and thus more details about the semiconductor device 600 can be found in the above embodiments and will not be elaborated herein.

The discussion herein included numerous illustrative figures that showed various portions of a semiconductive device and a method for manufacturing such semiconductor device. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for making a semiconductor device, comprising:
providing a substrate having a first surface and a second surface opposite to the first surface, wherein a plurality of conductive pillars are formed on the second surface of the substrate;
forming a polyimide layer on the second surface of the substrate to cover the plurality of conductive pillars;
mounting a first electronic component on the first surface of the substrate; and
forming a first encapsulant on the first surface of the substrate to cover the first electronic component.

2. The method of claim 1, wherein forming the polyimide layer on the second surface of the substrate comprises:
providing a varnish comprising polyimide material;
immersing the plurality of conductive pillars into the varnish; and
heating the varnish to form the polyimide layer on the second surface of the substrate.

3. The method of claim 1, wherein forming the polyimide layer on the second surface of the substrate comprises:
providing a varnish comprising polyimide material;
spin-coating the second surface of the substrate with the varnish; and
heating the varnish to form the polyimide layer on the second surface of the substrate.

4. The method of claim 1, further comprising:
planarizing the polyimide layer before mounting the first electronic component on the first surface of the substrate.

5. The method of claim 1, wherein forming the first encapsulant comprises:
providing a molding apparatus comprising a top chase and a bottom chase, wherein a molding material is held in the bottom chase;
attaching the polyimide layer onto the top chase of the molding apparatus; and
moving the top chase and the bottom chase close to each other to compress the molding material to cover the first electronic component on the first surface of the substrate, thereby forming the first encapsulant on the first surface of the substrate.

6. The method of claim 5, further comprising:
separating the top chase and the bottom chase from each other; and
removing the substrate from the molding apparatus.

7. The method of claim 1, further comprising:
grinding the polyimide layer to expose the plurality of conductive pillars after forming the first encapsulant on the first surface of the substrate.

8. The method of claim 6, further comprising:
mounting a second electronic component on a first set of the plurality of conductive pillars; and
forming a second encapsulant on the polyimide layer, wherein the second encapsulant covers the plurality of conductive pillars and the second electronic component.

9. The method of claim 1, further comprising:
removing the polyimide layer from the second surface of the substrate after forming the first encapsulant on the first surface of the substrate

10. The method of claim 9, further comprising:
mounting a second electronic component on a first set of the plurality of conductive pillars; and
forming a second encapsulant on the second surface of the substrate, wherein the second encapsulant fills gaps among the plurality of the conductive pillars and covers the second electronic component.

11. The method of claim 8, further comprising:
planarizing the second encapsulant to expose the second electronic component;
forming one or more cavities in the second encapsulant to expose top surfaces of a second set of the plurality of conductive pillars; and
forming a bump in each of the one or more cavities to electrically connect a respective conductive pillar.

12. The method of claim 11, wherein forming the bump in each of the one or more cavities comprises:
printing solder paste into the one or more cavities of the second encapsulant; and
reflowing the solder paste to form the bump.

13. The method of claim 12, further comprising:
forming an electromagnetic interference (EMI) shielding layer, wherein the EMI shielding layer at least covers the first encapsulant.

14. The method of claim 1, wherein the plurality of conductive pillars comprises a copper pillar.

15. A semiconductor device, comprising:
a substrate having a first surface and a second surface opposite to the first surface;
a plurality of conductive pillars disposed on the second surface of the substrate;
a polyimide layer disposed on the second surface of the substrate and surrounding the plurality of conductive pillars;
a first electronic component mounted on the first surface of the substrate; and
a first encapsulant disposed on the first surface of the substrate and covering the first electronic component.

16. The semiconductor device of claim 15, wherein a top surface of each of the plurality of conductive pillars is substantially flush with a top surface of the polyimide layer.

17. The semiconductor device of claim 16, further comprising:
a second electronic component mounted on a first set of the plurality of conductive pillars;
a plurality of bumps disposed on and electrically connected with a second set of the plurality of conductive pillars, respectively; and
a second encapsulant disposed on the polyimide layer and surrounding the plurality of bumps and the second electronic component.

18. The semiconductor device of claim 17, further comprising:
an electromagnetic interference (EMI) shielding layer at least covering the first encapsulant.
